(19) United States
(12) Patent Application Publication
(10) Pub. No.: US 2014/0038421 A1
(43) Pub. Date: Feb. 6, 2014

(54) Deposition Chamber and Injector

(71) Applicants: Kai-Lun Kuo, Zhongli City (TW); Ming-Te Chen, Hsin-Chu (TW); Hsing-Jui Lee, Hsin-Chu (TW); Yu-Yen Lin, Zhubei City (TW); Yen-Chen Lin, New Taipei City (TW)

(72) Inventors: Kai-Lun Kuo, Zhongli City (TW); Ming-Te Chen, Hsin-Chu (TW); Hsing-Jui Lee, Hsin-Chu (TW); Yu-Yen Lin, Zhubei City (TW); Yen-Chen Lin, New Taipei City (TW)

(73) Assignee: TAIWAN SEMICONDUCTOR MANUFACTURING COMPANY, LTD., Hsin-Chu (TW)

(21) Appl. No.: 13/564,410

(22) Filed: Aug. 1, 2012

(51) Int. Cl. C23C 16/455; H01L 21/02

(52) U.S. Cl. 438/758; 118/715; 257/E21.002

(57) ABSTRACT

A system and method are disclosed for processing semiconductors. An embodiment comprises a reaction chamber for processing wafers and having walls tapering at an angle that is greater than 0 degrees and less than about 35 degrees from a first end optionally having a diameter of 341 to 380 millimeters to a second end optionally having a diameter of 300 to 340 millimeters at a second end, with gas flow from the first end to the second end, and having at least one deposition injector near the first end of the reaction chamber and having a plurality of injector openings that disperse injection material across a cross section of the reaction chamber for forming a deposition layer.

### BACKGROUND

Generally, semiconductor devices are formed using photolithography, where various layered structures are applied to an underlying substrate. The features of the semiconductor device structures are defined by masks, with new material deposited on underlying layers but defined and bounded by the masked areas.

One technique used to reduce the size, or pitch, of features defined in semiconductor devices is multiple pattering or using a sacrificial spacer. A spacer is a film layer formed on a pre-patterned feature. A spacer is formed by deposition or reaction of the film on the previous pattern, followed by etching to remove all the film material on the horizontal surfaces, leaving only the material on the sidewalls. By removing the original patterned feature, only the spacer is left. However, since there are two spacers for every line, the line density has now doubled. The spacer technique is applicable for defining narrow gates at half the original lithographic pitch, for example. As spacer materials are commonly hardmask materials, their post-etch pattern quality tends to be superior compared to photoresist profiles after etch, which are generally plagued by line edge roughness.

Similarly, various deposition layers, such as passivation layers, insulators, metal layers or the like may be deposited on a semiconductor substrate, using spacer or photoresist masking techniques. In order to effectively deposit or bring the various chemicals and reagents into contact with a semiconductor substrate, techniques such as chemical vapor deposition (CVD), physical vapor deposition (PVD) and epitaxy may be used. This is frequently done in a reaction, or deposition, chamber where the temperature, chemical composition and pressure of the environment can be tightly controlled. Gases are commonly introduced into the deposition chamber and allowed to flow over substrate wafers for deposition on, or reaction with, the wafer surface. However, the decreasing size of semiconductor device features requires that the layers achieve increasingly uniform features to maintain the desired physical properties of the resulting semiconductor device. In particular, the variations in devices from wafer to wafer (WtW) in a particular deposition run, and variations between devices within a wafer (WiW), can lead to variations in the physical properties, and in some instances, may cause some devices to be so out of tolerance that they are unsuitable for packaging.

### BRIEF DESCRIPTION OF THE DRAWINGS

For a more complete understanding of the present embodiments, and the advantages thereof, reference is now made to the following descriptions taken in conjunction with the accompanying drawings, in which:

FIG. 1A is a diagram illustrating a deposition chamber device according to various embodiments of the present disclosure;

FIG. 1B is a diagram illustrating an embodiment of the present disclosure;

FIG. 2 is a cross-sectional diagram illustrating a deposition injector according to various embodiments of the present disclosure; and

FIG. 3 is a diagram illustrating a deposition injector arrangement according to various embodiments of the present disclosure.

### DETAILED DESCRIPTION OF ILLUSTRATIVE EMBODIMENTS

The making and using of the present embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosed subject matter, and do not limit the scope of the different embodiments.

Embodiments will be described with respect to a specific context, namely a semiconductor deposition chamber. Other embodiments may also be applied, however, to other deposition techniques, such as thin film coatings, powder coating, painting, or the like.

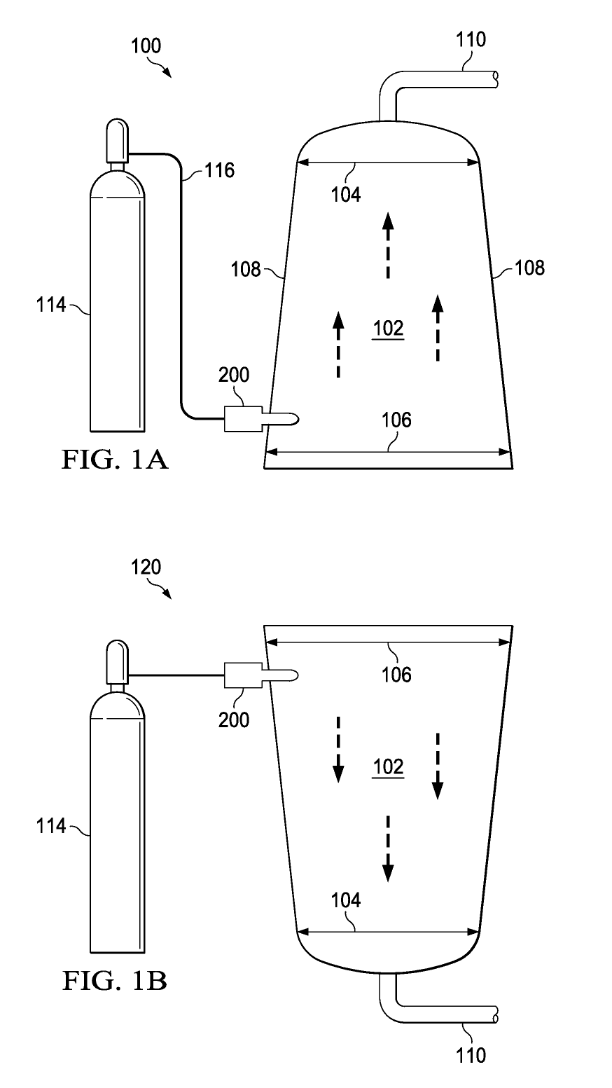

FIG. 1A illustrates a deposition chamber device 100 according to one embodiment of the present principles. In a typical deposition process, the substrate is exposed to one or more volatile precursors in the reaction chamber 102, which react and/or decompose on the substrate surface to produce the desired deposit. This may be accomplished by injecting a desired reactive gas, either by vaporizing a liquid prior to injection, or directly injecting a gas. The injected gases may also be carried into the reaction chamber 102 by a carrier gas, or mixed in the reaction chamber 102 with additional reactive gases. Frequently, volatile or undesirable by-products are also produced, which are removed via an outflow opening 110 by gas flow through the reaction chamber 102.

In this embodiment, the shaped reaction chamber 102 has sloping walls 108 and an upper chamber diameter 104 smaller than the lower chamber diameter 106, resulting in a tapered reaction chamber 102. Where the reaction chamber has a regular or radially symmetrical reaction chamber 102, the reaction chamber 102 shape may be characterized as conical, or having a truncated cone shape, that is, a cone with the top portion removed. While a conical reaction chamber 102 is shown, the reaction chamber may be radially irregular, or have another non-tubular interior contour.

In one useful embodiment, the walls 108 defining the reaction chamber 102 may have a slope of greater than 0 degrees and less than about 35 degrees from vertical, or from the centerline of the reaction chamber. The upper chamber diameter 104 may advantageously be between about 300 and 340 millimeters, and the lower chamber diameter 106 may advantageously be between about 341 and 380 millimeters. However, while these dimensions may be preferable in certain situations, skilled artisans will recognize that the width or taper of the reaction chamber 102 may be varied according to any requirement imposed by the system or task. Thus, where a reaction chamber is configured to accept larger or smaller wafers, or a larger or smaller number of wafers, the chamber may be enlarged or shrunk. Similarly, the taper of the reaction chamber walls 108 may be varied based on the environmental conditions, such as gas flow rates or nature of the deposition material being flowed through the reaction chamber 102.

While the drawings illustrating embodiments of the presented principles show the reaction chamber 102 with the narrow, exit end upwards and gases subsequently flowing upwards, the presented principles are not limited to such an orientation. Vertical reaction chambers are used, in part, because any falling debris may only land on a top wafer when the wafers are loaded into the reaction chamber horizontally, and arranged vertically on top of each other. In another embodiment, a horizontal reaction chamber 102 may have wafers arranged on edge, side by side. In yet another alternative embodiment 120 as shown in FIG. 1B, the reaction chamber 102 may be vertical, but with the larger diameter 106 end of the reaction chamber 102 on top, so that the gas flows downward, to the reaction chamber's 102 narrow end 104. In such an embodiment, the deposition injectors 200 may be disposed near the top of the deposition chamber 102, with the outflow opening 110 disposed below, or at the bottom of, the deposition chamber 102.

Additionally, one or more deposition injection injectors 200 may be disposed within the walls 108 of the reaction chamber 102. In particularly useful embodiments, the deposition injectors 200 may be disposed at, or near, the larger end 106 of the reaction chamber 102. A gas supply 114 may be connected directly or via any type of gas transfer system 116 to the injectors 200. Additionally, the gas supply 114 may provide a liquid injection material, and the gas transfer system 116 may include components for mixing one or more materials prior to injection, or for evaporating a liquid or other non-gaseous material prior to injection.

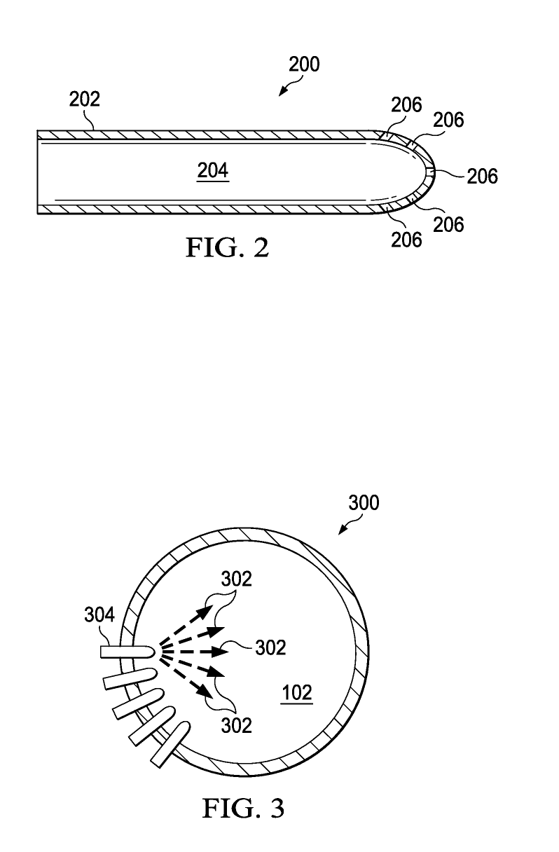

FIG. 2 illustrates a cross section of a deposition injector 200 according to the present principles. In particularly useful embodiments, the injector 200 will be configured to disperse injection material at a determinable rate and over a broad area. The multiport injector 200 has an injector cavity 204 enclosed by an injector wall 202, which has multiple injector openings 206. Skilled practitioners will recognize that a deposition injector 200 may also include control structures such as valves or the like, which are omitted here.

The present embodiments of a multiport deposition injector 200 may, for example, include an injector 200 with a generally hemispherical shaped chamber-facing end, with injector openings 206 spaced across three dimensions of the injector's hemispherical end. Some embodiments of the deposition injector 200 may include between about 6 and 20 injector openings 206 and may, in particularly useful embodiments, have about 12 injector openings 206. Skilled practitioners will recognize that the injector shape may be varied depending on the desired deposition injector 200 coverage. For example, the deposition injector 200 may be spherical, triangular, formed into a T-shape, or the like.

The openings 206 may also be distributed in a radial pattern around the centerline of a hemispherically shaped injector 200 to provide greater dispersal of material as it is injected into a reaction chamber 102. Alternatively, an alternative embodiment may be where the injector openings 206 are arranged in a line across the face of the hemispherical end. In such an embodiment, the rows of injector openings 206 may have one or more rows perpendicular to the flow of gases through the reaction chamber 102. However, depending on use and desired material injection and dispersal properties, any shape for the injector nozzle 200 and injector openings 206 may be used.

FIG. 3 is a diagram illustrating a deposition injector arrangement 300 according to the present principles. An array of multiport deposition injectors 304 may be disposed in a deposition chamber device 100 and situated to deliver deposition material to the reaction chamber 102. The multiple ports 206 in a multiport deposition injector 200 disperse deposition material via a wide path 302 into the reaction chamber 102. In particularly useful embodiments, the multiport deposition injector 200 will disperse the injection material substantially across a cross section of the reaction chamber 102. Thus, the injection gas is more evenly spread throughout the reaction chamber 102 as it is drawn towards the outflow opening 110.

In particularly useful embodiments, one or more injectors may be arranged near the bottom of a shaped reaction chamber 102. Thus, the flow of gasses from the injector array 304 may flow generally upward, from the wider diameter end of the reaction chamber 102 to the narrower end of the reaction chamber 102.

Additionally, the environmental conditions for processing or deposition may also be advantageously varied based on the type of process or base used for deposition. A wide variety of injection materials, injection gases or deposition gases may also be used. Such injection materials need not necessarily be limited to deposition only, and may be used to interact with, react with or modify the surface of the wafers, or to deposit material on the wafers. Thus, the presented principles may be used to develop an oxide on the surface of a wafer by reacting water vapor or oxygen (wet or dry oxidation) with the surface of a silicon wafer. Alternatively, other insulating or masking material, such as a nitride, may be deposited in the surface of a wafer. For example, nitride film formation using a hexachlorodisilane (HCD) base may take place in an environment having an HCD flow rate of 10-100 sccm, an NH3 flow rate of 300-3000 sccm, a temperature of 500-600 C and a pressure of 0.1-1 ton. By way of further example, nitride film formation using a dichlorosilane, SiH2Cl2 (DCS) base may be in an environment having a DCS flow rate of 100-400 sccm, a NH3 flow rate of 300-1200 sccm, a temperature of 600-700 C, and a pressure of 0.1-3 torr. While the above cited embodiments refer to insulating nitrides and oxides, the presented principles may also be used for semiconductor fabrication procedures such as doping, metallization, or the like. Additionally, the presented principles may be advantageously applied outside of the semiconductor manufacturing arena, in fields such as painting, power coating, optical lens film deposition, or the like.

Skilled artisans will recognize that in order to maintain a desired environment within the reaction chamber 102, control components might be a part of the deposition chamber device 100. For example, a vacuum pump may be employed, attached, for example, to the outflow opening 110 to draw gases through the reaction chamber 102 and maintain the appropriate pressure or vacuum. By way of further example, the deposition chamber device 100 may also optionally include a furnace heater, or other component for regulating and raising the reaction chamber 102 environment to a desired operating or reaction temperature.

The multiport deposition injector 200 combined with a shaped reaction chamber 102 has resulted in a greater consistency in feature sizes within wafers and between wafers in a single deposition batch. In particular, layers such as silicon nitrides that may be used as spacers and hard marks may be affected by deposition uniformity. In these instances, since the hard masks are generally the sidewalls remaining after a mask-and-cleaning procedure, sidewall formation and dimensional uniformity are critical uniformity considerations. For example, the drain saturation current in MOSFET devices is critically linked to the feature uniformity of the MOSFET. The drain saturation current may frequently be measured for devices across a wafer to determine the electrical characteristics of the MOSFET devices on the wafer. In MOSFETs in particular, the thickness of the MOSFET gate oxide, as well as the dimensions of the gate-channel overlap, affect the saturation current. Reducing the variations in masking and oxide deposition can affect the dimensions of the transistor structures, causing less saturation fluctuation from device to device, increasing the yield of a particular wafer.

The combination of a multiport deposition injector 200 and shaped reaction chamber 102 may increase the yield of usable devices formed therein. For example, when using a 28 nanometer fabrication process, the critical device uniformity increases about 10%. For silicon nitride spacers, the within wafer thickness variation range in feature sizes improves from about 1 nanometer to about 0.5 nanometers and the wafer-to-wafer variation improves from about 5 angstroms (0.5 nanometers) to about 3 angstroms (0.3 nanometers).

In particular, when examining a single wafer, areas at the periphery of the wafer tend to have a larger number of failures, or out-of-tolerance devices than do areas at the center of the wafer. With the more uniform distribution across the surface of the wafer provided by embodiments of the presented principles, the yield failure rate of devices in the outer quarter of the wafer can be improved using the presented principles instead of a standard tube and injector.

Dispersion injectors with narrow injection patterns tend to cause gases in the reaction chamber to react incompletely, and cause a gas density distribution higher on one side of the reaction chamber, generally near the injector itself. The presented principles more evenly disperse gases through a cross section of the reaction chamber 102. This permits the deposition material sufficient time to react among the injected materials and then react with, or deposit on, a wafer surface. For example, nitride deposition using a DCS base, SiH2Cl2 reacts in gaseous form with gaseous NH3 within the reaction chamber 102 to form Si3N4 (silicon nitride, solid), HCl (hydrochloric acid, gaseous) and H2 (hydrogen, gaseous). The nitride forms on the interior surfaces of the reaction chamber, including the wafer surfaces. Use of the presented principles increases the uniformity of nitride layer formation, and reduces the rate of individual device failure across a wafer, and in particular, at the edge of the wafer.

In order to use a system embodying the presented principles, an operator would place wafers into a reaction chamber 102 and inject an injection gas into the reaction chamber 102 via the deposition injectors 302. The gas flows at a predetermined flow rate from the first, wider end 106 of the reaction chamber 102 to the second, narrower end 104 of the reaction chamber 102. The deposition gas is injected through one or more injector openings 206 and will disperse across a cross section of the reaction chamber 102. The injection gas will deposit a layer of material on at least one surface the wafers via an interaction between at least the active gas and wafer surface.

Although the present embodiments and their advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A system for creating a deposition layer comprising:
a reaction chamber having sidewalls tapering at a predetermined angle from a first diameter at a first end to a second diameter at a second end and configured to accept placement of a target wafer;
at least one deposition injector disposed within a sidewall near the first end of the reaction chamber; and
a plurality of injector openings disposed in the deposition injector, the injector openings configured to disperse injection material substantially across a cross section of the reaction chamber.

2. The system of claim 1, wherein the first diameter at the first end is between about 341 and 380 millimeters, and second diameter at the second end is between about 300 and 340 millimeters.

3. The system of claim 1, wherein the predetermined angle of the sidewall taper is greater than 0 degrees and less than about 35 degrees from the centerline of the reaction chamber.

4. The system of claim 1, wherein the injection material forms a deposition layer on a surface of at least one wafer.

5. The system of claim 1, wherein the deposition injector has between about 6 and 20 injector openings.

6. The system of claim 1, wherein the deposition reaction chamber is aligned vertically, with the first end above the second end.

7. The system of claim 1, wherein the reaction chamber is maintained at a predetermined temperature and pressure.

8. The system of claim 1, further comprising an outflow opening through which gases are drawn out of the reaction chamber, the outflow opening disposed in the reaction chamber to draw injection material and at least a portion of additional gases from the first end of the reaction chamber through the second end of the reaction chamber.

9. A system for processing a semiconductor wafer comprising:
a reaction chamber having sidewalls forming a first end with a first diameter and a second end with a second diameter smaller than the first diameter, and configured to accept placement of a target wafer, the reaction chamber configured to maintain a predetermined temperature and a predetermined pressure, and to draw gas from the first end to the second end;
at least one deposition injector disposed within a sidewall near the first end of the reaction chamber; and
a plurality of injector openings disposed in the deposition injector and providing a path for movement of a gas injection material from an interior cavity of the injector to the reaction chamber, the injector openings arranged and configured to disperse the injection material substantially across a cross section of the reaction chamber substantially perpendicular to a centerline of the reaction chamber extending from the first end to the second end.

10. The system of claim 9, wherein injection material forms a hard mask on a surface of the wafer.

11. The system of claim 9, wherein the first diameter is between about 341 and 380 millimeters.

12. The system of claim 9, wherein the second diameter is between about 300 and 340 millimeters.

13. The system of claim 9, wherein the sidewalls taper towards the centerline of the reaction chamber at an angle greater than 0 degrees and less than about 35 degrees from the centerline.

14. The system of claim 9, wherein the reaction chamber is aligned vertically, with the first end below the second end.

15-20. (canceled)

21. An apparatus, comprising:
a reaction chamber having a first diameter at a first end larger than a second diameter at a second end, sidewalls of the reaction chamber extending from the first end to the second end and forming a first angle from a centerline of the reaction chamber, the reaction chamber configured to hold a target wafer therein; and
a plurality of deposition injectors disposed in the sidewall nearest the first end, each of the plurality of deposition injectors having at least one injector opening arranged and configured to disperse an injection material substantially across a cross section of the reaction chamber substantially perpendicular to the centerline and at a predetermined flow rate.

22. The apparatus of claim 21, wherein the reaction chamber is aligned vertically, with the first end below the second end.

23. The apparatus of claim 21, wherein the reaction chamber is aligned vertically, with the first end above the second end.

24. The apparatus of claim 21, wherein the first diameter is between about 341 and 380 millimeters.

25. The apparatus of claim 21, wherein the second diameter is between about 300 and 340 millimeters.

26. The apparatus of claim 21, wherein the sidewalls taper toward the centerline of the reaction chamber with the angle greater than 0 degrees and less than about 35 degrees from the centerline of the reaction chamber.
